(19) United States
(12) Patent Application Publication
(10) Pub. No.: US 2005/0191767 A1
(43) Pub. Date: Sep. 1, 2005

(54) Focused ion beam circuit repair using a hardmask and wet chemistry

(76) Inventors: Henry L. Edwards, Garland, TX (US); Jeffrey L. Large, Dallas, TX (US); John F. West, Plano, TX (US)

Correspondence Address: TEXAS INSTRUMENTS INCORPORATED, P O BOX 655474, M/S 3999, DALLAS, TX, 75265, US

(21) Appl. No.: 10/791,461

(22) Filed: Mar. 1, 2004

(51) Int. Cl. H01L 21/00

(52) U.S. Cl. 438/4

(57) ABSTRACT

An embodiment of the invention is a method of integrated circuit repair that includes removing the top dielectric layer 160 in at least one location using a FIB and etching exposed areas of a top metal layer 171 using a wet chemistry process. This method also includes etching selected portions of one or more dielectric interconnect layers 140, 141 using a FIB, and then using a FIB to either cut a selected portion of a metal interconnect layer 130, 131 or connect a selected portion of a metal interconnect layer 130, 131. Another embodiment of the invention is a method of integrated circuit repair that forms a top dielectric layer 80 over the circuit 10 and then removes the top dielectric layer 80 in at least one location using a FIB. The exposed areas of a top metal layer 70 are etched using a wet chemistry process. Selected portions of one or more dielectric interconnect layers 60, 40 are etched using a FIB, and then a FIB is used to either cut a selected portion of a metal interconnect layer 30 or connect a selected portion of a metal interconnect layer 30.

### BACKGROUND OF THE INVENTION

This invention relates to focused ion beam repair of the metal interconnect layers of an integrated circuit.

### BRIEF DESCRIPTION OF THE DRAWINGS

FIG. 1 is a cross-sectional view of a top portion of an integrated circuit in accordance with the invention.

FIGS. 2-4 are cross-sectional diagrams showing a method for performing a FIB circuit repair in accordance with the invention.

FIGS. 5-7 are cross-sectional diagrams showing an alternative method for performing a FIB circuit repair in accordance with the invention.

### DETAILED DESCRIPTION OF THE INVENTION

The present invention is described with reference to the attached figures. The figures are not drawn to scale and they are provided merely to illustrate the invention. Several aspects of this invention are described below with reference to example applications for illustration. It should be understood that numerous specific details, relationships, and methods are set forth to provide a full understanding of the invention. However, one skilled in the relevant art will readily recognize that the invention can be practiced without one or more of the specific details or with other methods. In other instances, well-known structures or operations are not shown in detail to avoid obscuring the invention.

Referring to the drawings, FIG. 1 is a cross-sectional view of a top portion of an integrated circuit 10 in accordance with the invention. Specifically, FIG. 1 shows an upper level metal interconnect layer 20 having metal interconnects 30 that properly route electrical signals or power throughout the integrated circuit. In the example application, the metal interconnects 30 are comprised of Cu (with a thin layer of barrier metal such as TaN or Ta, not shown); however, other metals such as Al, W, TiN, or Ti may be used. The upper level metal interconnect layer 20 also contains regions of dielectric material 40 that electrically insulate the metal interconnects 30. The dielectric material 40 is preferably comprised of any low-k (i.e. low dielectric constant) material, such as Organo-Silicate Glass (“OSG”) or Fluorinated Silicon Glass (“FSG”).

The example metal interconnect layer 20 is a top metal interconnect level formed over a semiconductor body 50. Semiconductor body 50 usually contains other metal interconnect levels that are located below—and are possibly electrically interconnected to—the top metal interconnect level 20. Together, the metal interconnect levels properly route all of the power and electrical signals throughout the integrated circuit. The semiconductor body 50 also contains a device level (not shown) that is located below all of the metal interconnect levels. The device level may contain passive elements and active elements such as transistors. Moreover, the device level may contain various well and substrate technologies.

As shown in FIG. 1, there is a top layer of dielectric material 60 located over the metal interconnect layer 20. The top dielectric layer 60 is an overcoat layer that protects the integrated circuit 10 (e.g. provides a hermetic seal against ambient) and helps to electrically insulate the metal interconnects 30 of the upper metal interconnect layer 20.

In the example integrated circuit 10 shown in FIG. 1, a metal cap or metal interconnect layer 70 is located over the top dielectric layer 60. In this example application, the top metal layer 70 is a Bond Over Active Circuit (“BOAC”) layer and it is comprised of Cu (though it could be comprised of any conductive material). Generally, a BOAC layer is thicker than a metal interconnect layer and it is used to create extra electrical connections after the integrated circuit has been fabricated.

Focused Ion Beam (“FIB”) circuit repair is often used to change the electrical connections of an integrated circuit after it has been cut from the semiconductor wafer and mounted into a device package. Before performing FIB circuit repair the device package is removed from the electrical system. During FIB circuit repair, the metal lines located anywhere in the integrated circuit may be cut (to disconnect a signal) or coupled to another metal line (to form an additional electrical connection). FIB circuit repairs facilitate the testing and analysis of an altered circuit design before the revised design is implemented into the manufacturing process (namely, before new masks or reticles are created). In addition, FIB circuit repairs are done to adjust the timing of circuits by altering resistance or capacitance levels.

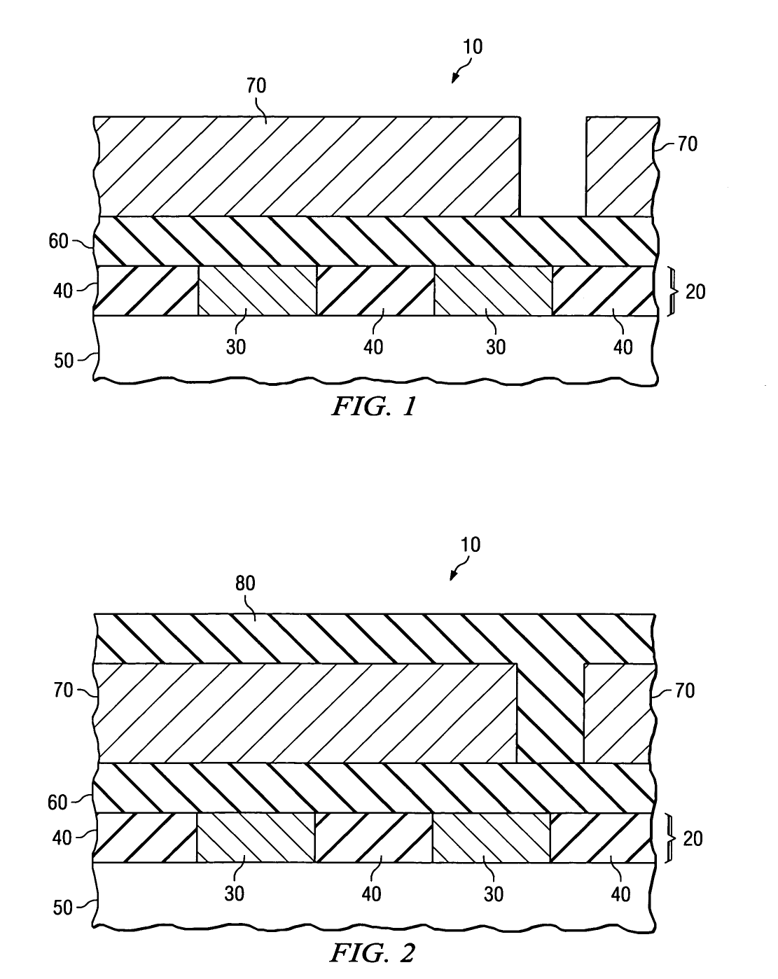

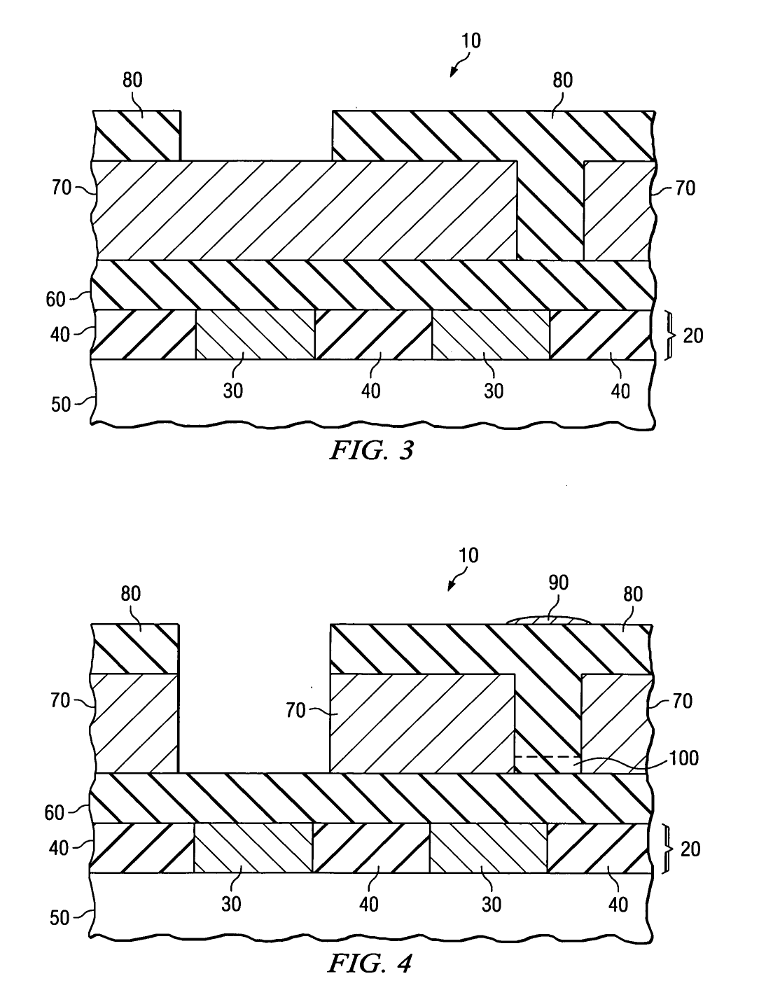

FIGS. 2-4 are cross-sectional diagrams showing a method for performing a FIB circuit repair in accordance with the invention. First, as shown in FIG. 2; a top dielectric layer 80 is formed on the surface of the integrated circuit 10. In the best mode application, the top dielectric layer 80 is comprised of Si₃N₄ and it is a film that is approximately 1000 Å thick. However, it is within the scope of the invention to use other dielectric materials such as SiₓO_{y}H_{z}, SiₓC_{y}H_{z}, or Si_{w}OₓN_{y}H_{z}. Furthermore, the top dielectric layer 80 may have any thickness ranging from a monolayer to 10000 Å. The top dielectric layer 80 may be formed using any manufacturing process such as Physical Vapor Deposition (“PVD”) or Chemical Vapor Deposition (“CVD”), or may simply be applied in a low-tech manner (such as with a spray bottle).

Now, as shown in FIG. 3, a FIB is used to remove selected portions of the top dielectric layer 80. In the typical situation where multiple changes are being made to the integrated circuit 10, the FIB will be used to remove portions of the top dielectric layer 80 in multiple locations (i.e. in multiple “edit areas”). In the best mode application, standard FIB etch techniques are used to etch the top dielectric layer 80. For example, the FIB machine may use a Ga Liquid Metal Ion (“LMI”) source with XeF₂ gas. In the best mode application, the final etched top dielectric layer 80 will be used as a patterned hardmask for etching the metal BOAC layer 70 and also used to protect the integrated circuit against unwanted electrical shorts during the remaining FIB circuit repair process.

In accordance with the invention, the exposed portions of the generally thick Cu BOAC metal layer 70 are now etched. As shown in FIG. 4, some of the etched metal from the BOAC top metal layer 70 may re-deposit in areas 90 on the integrated circuit 10. However, the insulating top dielectric layer hardmask 80 prevents unwanted electrical shorts that could have been caused by the etched metal re-depositing in unwanted locations such as region 100.

In the best mode application, the exposed portions of the metal BOAC layer 70 are etched using standard wet chemistry techniques. For example, a machine such as the Mercury or Xcalibur (manufactured by FSI), or a DNS Wet Hood (manufactured by DNS) may use Nitric Acid (or other CU etching chemistry) in the fluid, vapor, or bath to remove all exposed regions of the metal layer 70 and create a planar surface on the exposed portions of the underlying top dielectric layer 60. However, other techniques to etch the metal layer 70, such as plasma etch, are within the scope of the invention.

Standard FIB circuit repair techniques are now used to etch (and thereby electrically disconnect) an underlying metal interconnect 30. Or, standard FIB circuit repair techniques are used to strap (and thereby electrically connect) an underlying metal interconnect 30 to another metal interconnect 30 in the same upper metal interconnect layer 20 or a lower metal interconnect layer (not shown). As an example, the FIB may use a Ga LMI beam source and Pt conductive gas to strap two metal interconnects and then deposit electrically insulating material in the voids.

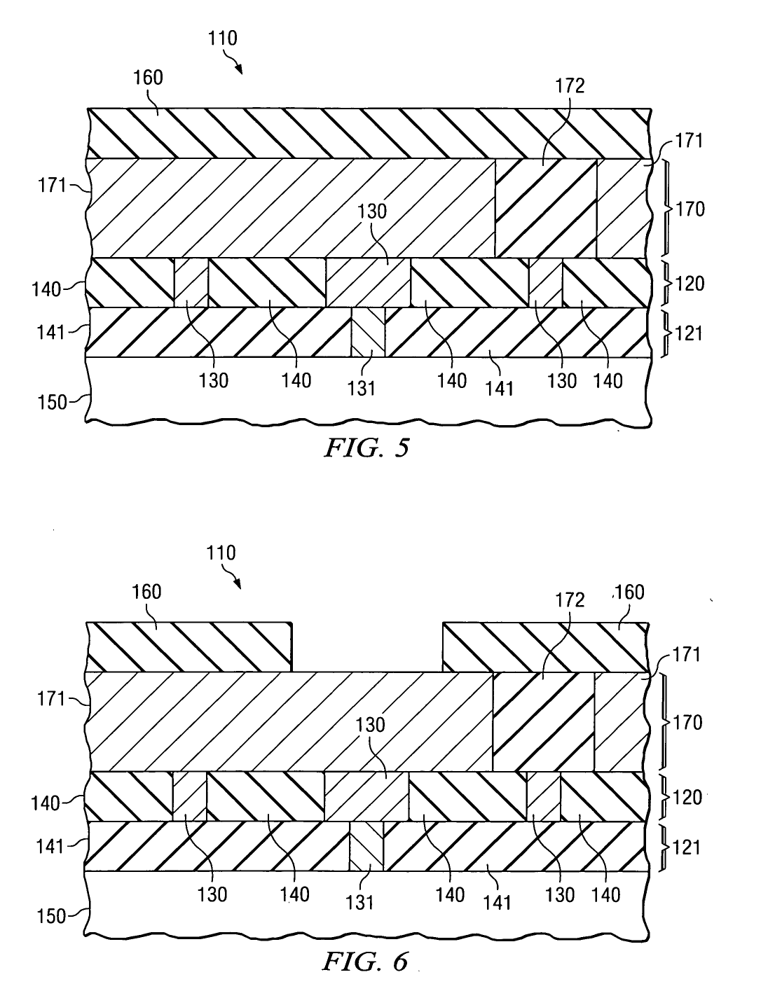

FIGS. 5-7 are cross-sectional diagrams showing an alternative method for performing a FIB circuit repair in accordance with the invention. FIG. 5 is a cross section view of top portion of an integrated circuit 110 in accordance with another embodiment of the invention. Specifically, FIG. 5 shows the top two metal interconnect layers of an alternative integrated circuit 110. The upper metal interconnect layer 120 is similar to the upper level metal interconnect layer 20 shown in FIG. 1. The upper metal interconnect layer 120 has metal interconnects 130 and dielectric portions 140. The second metal interconnect layer 121 is also similar to the upper level metal interconnect layer 20 shown in FIG. 1. The second metal interconnect layer 121 has metal interconnects 131 and dielectric portions 141. Additional interconnect layers and the device layer are contained in the remainder of the semiconductor body 150.

In the example application, there is a top metal layer 170 that contains metal interconnects 171 that serve as power buses separated by dielectric insulation 172. The power buses 171 may be comprised of any material such as Cu, Al, W, NiPd, or Ti. Over the top metal layer 170 is the top dielectric layer 160 that is generally the protective overcoat layer. The protective overcoat layer 160 may be comprised of any material such as SiON.

In the best mode application, the protective overcoat 160 is used as the hardmask for the subsequent wet etch of the top metal layer 170. Therefore, there is no need for an additional hardmask—such as the hardmask layer 80 shown in FIG. 2.

As shown in FIG. 6, standard FIB techniques are used to remove selected portions of the top dielectric layer 160. The FIB may be used to remove the top dielectric layer 160 in multiple locations. In the best mode application, the top dielectric layer 160 is etched using standard FIB etch techniques. For example, the FIB machine may use a Ga LMI source with XeF₂ gas. In the best mode application, the final etched top dielectric layer 160 (i.e. the protective overcoat layer) will be used as a patterned hardmask for etching the metal interconnects 171 and also used to protect against unwanted shorts during the remaining FIB circuit repair process.

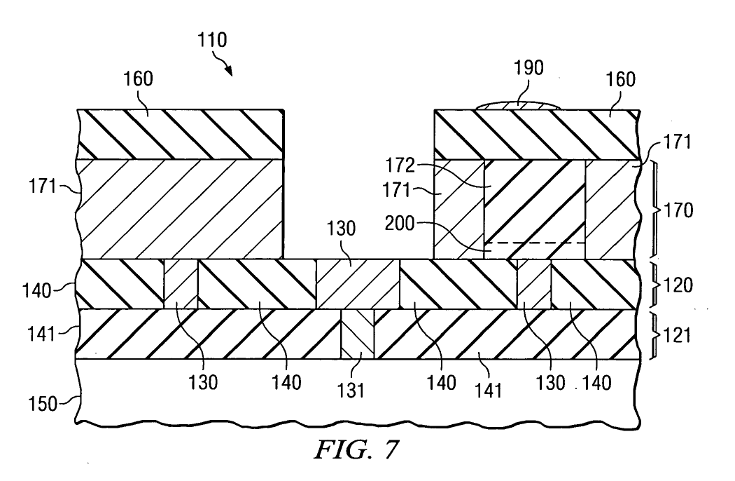

As shown in FIG. 7 and in accordance with the invention, the exposed Cu metal interconnects 171 are etched simultaneously. As with the previous example, some of the etched metal from the top metal layer 170 may re-deposit in areas 190 on the integrated circuit 110. However, the insulating top dielectric layer hardmask 160 prevents unwanted electrical shorts that could have been caused by the etched metal re-depositing in unwanted locations such as region 200.

In the best mode application, the exposed portions of the top metal layer 170 are etched using standard wet chemistry techniques. For example, a machine such as the Mercury or Xcalibur, or a DNS Wet Hood may use Nitric Acid in the fluid, vapor, or bath to remove all exposed regions of the top metal layer 170 and create a planar surface on the exposed portions of the underlying metal layer 120. However, other techniques to etch the metal layer 170, such as plasma etch, are within the scope of the invention.

Standard FIB circuit repair techniques are now used to etch an underlying metal interconnect 130; or used to connect an underlying metal interconnect 130 to another metal interconnect 130 in the same upper metal interconnect layer 120 or a lower metal interconnect layer such as layer 121. As an example, the FIB may use a Ga LMI beam source and Pt conductive gas to strap two metal interconnects and then deposit electrically insulating material into the voids.

Various modifications to the invention as described above are within the scope of the claimed invention. For example, the interconnect layers 20, 120, 121 shown in the drawings are single damascene metal interconnect layers. However, it is within the scope of the invention to use different interconnect structures such as dual damascene metal interconnect layers. Instead of BOAC, the top metal cap layer 70 may be a power bus or an additional metal interconnect layer. Furthermore, the top metal layer 70 may be comprised of other metals such as Al, Ti or PI.

It is within the scope of the invention to have a hardmask layer 80, 160 that is non-homogenous or even multilayered. In addition, the patterned hardmask 80, 160 may be removed during or after the FIB circuit repair process. Furthermore, other sources or gases may be used in the FIB machine. Moreover, various dielectric or metal etch stop layers (sometimes called barrier layers) may be present. The metal interconnects 30, 130, 131 in the best mode application are comprised of copper; however, other materials such as Al, Ti and Pt may be used. Moreover, cleaning steps were omitted from the above description; however, the integrated circuit 10, 110 should be cleaned as necessary during its repair.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

1. A method of integrated circuit repair comprising:
removing the top dielectric layer in at least one location using a FIB;
etching exposed areas of a top metal layer using a wet chemistry process;
etching selected portions of one or more dielectric interconnect layers using a FIB; and
etching a selected portion of a metal interconnect using a FIB.

2. The method of claim 1 wherein said top dielectric layer is a protective overcoat layer.

3. The method of claim 1 wherein said top metal layer is a power bus layer.

4. The method of claim 1 wherein said step of etching selected portions of one or more dielectric interconnect layers using a FIB includes the use of a Gallium LMI source and Xenon DiFluoride gas.

5. The method of claim 1 wherein said step of removing the top dielectric layer in at least one location using a FIB includes the use of a Gallium LMI source and Xenon DiFluoride gas.

6. The method of claim 1 wherein said wet chemistry process uses a hood.

7. The method of claim 1 wherein said step of etching a selected portion of a metal interconnect using a FIB includes the use of a Gallium liquid metal ion source and Xenon DiFluoride gas.

8. The method of claim 1 wherein said wet chemistry process includes the use of Nitric Acid.

9. The method of claim 1 wherein said top metal layer contains copper.

10. The method of claim 1 wherein said metal interconnect contains copper.

11. A method of integrated circuit repair comprising:
removing the top dielectric layer in at least one location using a FIB;
etching exposed areas of a top metal layer using a plasma etch process;
etching selected portions of one or more dielectric interconnect layers using a FIB; and
etching a selected portion of a metal interconnect using a FIB.

12. A method of integrated circuit repair comprising:
removing the top dielectric layer in at least one location using a FIB;
etching exposed areas of a top metal layer using a wet chemistry process;
etching selected portions of one or more dielectric interconnect layers using a FIB; and
coupling a first metal interconnect portion to a second metal interconnect portion using a FIB.

13. The method of claim 12 wherein said first metal interconnect portion and said second metal interconnect portion are located in the same metal interconnect layer.

14. The method of claim 12 wherein said first metal interconnect portion and said second metal interconnect portion are located in different metal interconnect layers.

15. The method of claim 12 wherein said coupling a first metal interconnect portion to a second metal interconnect portion using a FIB includes the use of a Gallium LMI beam source and Platinum conductive gas.

16. The method of claim 12 wherein said top dielectric layer is a protective overcoat layer.

17. The method of claim 12 wherein said top metal layer is a power bus layer.

18. The method of claim 12 wherein said step of etching selected portions of one or more dielectric interconnect layers using a FIB includes the use of a Gallium LMI source and Xenon DiFluoride gas.

19. The method of claim 12 wherein said step of removing the top dielectric layer in at least one location using a FIB includes the use of a Gallium LMI source and Xenon DiFluoride gas.

20. The method of claim 12 wherein said wet chemistry process uses a hood.

21. The method of claim 12 wherein said wet chemistry process includes the use of Nitric Acid.

22. The method of claim 12 wherein said top metal layer includes copper.

23. The method of claim 12 wherein said first metal interconnect and said second metal interconnect includes copper.

24. A method of integrated circuit repair comprising:
removing the top dielectric layer in at least one location using a FIB;
etching exposed areas of a top metal layer using a plasma etch process;
etching selected portions of one or more dielectric interconnect layers using a FIB; and
coupling a first metal interconnect portion to a second metal interconnect portion using a FIB.

25. A method of integrated circuit repair comprising:
forming a top dielectric layer over said integrated circuit;
removing said top dielectric layer in at least one location using a FIB;
etching exposed areas of a top metal layer using a wet chemistry process;
etching selected portions of one or more dielectric interconnect layers using a FIB; and
etching a selected portion of a metal interconnect using a FIB.

26. The method of claim 25 wherein said top dielectric layer is formed using a PVD process.

27. The method of claim 25 wherein said top dielectric layer is formed using a CVD process.

28. The method of claim 25 wherein said top metal layer is a BOAC layer.

29. The method of claim 25 wherein said step of etching selected portions of one or more dielectric interconnect layers using a FIB includes the use of a Gallium LMI source and Xenon DiFluoride gas.

30. The method of claim 25 wherein said step of removing said top dielectric layer in at least one location using a FIB includes the use of a Gallium LMI source and Xenon DiFluoride gas.

31. The method of claim 25 wherein said wet chemistry process uses a hood.

32. The method of claim 25 wherein said step of etching a selected portion of a metal interconnect using a FIB includes the use of a Gallium LMI source and Xenon DiFluoride gas.

33. The method of claim 25 wherein said wet chemistry process includes the use of Nitric Acid.

34. The method of claim 25 wherein said top dielectric layer includes Silicon Nitride.

35. The method of claim 25 wherein said top metal layer contains copper.

36. The method of claim 25 wherein said metal interconnect contains copper.

37. A method of integrated circuit repair comprising:
forming a top dielectric layer over said integrated circuit;
removing the top dielectric layer in at least one location using a FIB;
etching exposed areas of a top metal layer using a plasma etch process;
etching selected portions of one or more dielectric interconnect layers using a FIB; and
etching a selected portion of a metal interconnect using a FIB.

38. A method of integrated circuit repair comprising:
forming a top dielectric layer over said integrated circuit;
removing the top dielectric layer in at least one location using a FIB;
etching exposed areas of a top metal layer using a wet chemistry process;
etching selected portions of one or more dielectric interconnect layers using a FIB; and
coupling a first metal interconnect portion to a second metal interconnect portion using a FIB.

39. The method of claim 38 wherein said first metal interconnect portion and said second metal interconnect portion are located in the same metal interconnect layer.

40. The method of claim 38 wherein said first metal interconnect portion and said second metal interconnect portion are located in different metal interconnect layers.

41. The method of claim 38 wherein said coupling a first metal interconnect portion to a second metal interconnect portion using a FIB includes the use of a Gallium LMI beam source and Platinum conductive gas.

42. The method of claim 38 wherein said top dielectric layer is formed using a PVD process.

43. The method of claim 38 wherein said top dielectric layer is formed using a CVD process.

44. The method of claim 38 wherein said top metal layer is a BOAC layer.

45. The method of claim 38 wherein said step of etching selected portions of one or more dielectric interconnect layers using a FIB includes the use of a Gallium LMI source and Xenon DiFluoride gas.

46. The method of claim 38 wherein said step of removing the top dielectric layer in at least one location using a FIB includes the use of a Gallium LMI source and Xenon DiFluoride gas.

47. The method of claim 38 wherein said wet chemistry process uses a hood.

48. The method of claim 38 wherein said wet chemistry process includes the use of Nitric Acid.

49. The method of claim 38 wherein said top dielectric layer includes Silicon Nitride.

50. The method of claim 38 wherein said top metal layer includes copper.

51. The method of claim 38 wherein said first metal interconnect and said second metal interconnect includes copper.

52. A method of integrated circuit repair comprising:
forming a top dielectric layer over said integrated circuit;
removing the top dielectric layer in at least one location using a FIB;
etching exposed areas of a top metal layer using a plasma etch process;
etching selected portions of one or more dielectric interconnect layers using a FIB; and
coupling a first metal interconnect portion to a second metal interconnect portion using a FIB.
